(19) United States
(12) Patent Application Publication
(10) Pub. No.: US 2008/0220616 A1
(43) Pub. Date: Sep. 11, 2008

(54) PROCESS FOR MANUFACTURING A SEMICONDUCTOR DEVICE

(75) Inventors: Takayuki Matsui, Chuo-ku (JP); Kota Hattori, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Chuo-ku (JP)

(21) Appl. No.: 12/031,275

(22) Filed: Feb. 14, 2008

(30) Foreign Application Priority Data
Mar. 7, 2007 (JP) 2007-056942

(51) Int. Cl. H01L 21/308; H01L 21/302

(52) U.S. Cl. 438/736; 438/735; 257/E21.219; 257/E21.232

(57) ABSTRACT

A process for manufacturing a semiconductor device, comprising: preparing a substrate in which a silicon-containing resist pattern is formed on a processed-material layer, dry-etching the processed-material layer using the silicon-containing resist pattern as a mask to form a processed-material layer pattern, ashing the silicon-containing resist pattern to leave a silicon-containing residual resist, immersing the substrate on which the silicon-containing residual resist remains into pure water to swell and deform the silicon-containing residual resist, and immersing the substrate on which the swelled and deformed silicon-containing residual resist remains into diluted hydrofluoric acid to remove the silicon-containing residual resist.

This application is based upon and claims the benefit of priority from Japanese patent application No. 2007-056942, filed on Mar. 7, 2007, the disclosure of which is incorporated herein in its entirety by reference.

### BACKGROUND OF THE INVENTION

1. Field of the Invention

The present invention relates to a process for manufacturing a semiconductor device where no residual resists remain on a substrate after dry etching.

2. Description of the Related Art

Semiconductor elements such as ICs and LSIs have been manufactured by forming a fine pattern on a substrate using photolithography. FIGS. 1 and 2 show specific manufacturing steps. First, a processed object 7 and a hard mask 2 are formed on a semiconductor substrate (not shown), on which is then applied a photoresist 1 (FIG. 1A). Next, the photoresist 1 is appropriately patterned by photolithography (FIG. 1B). Subsequently, using this photoresist as a mask, the hard mask 2 is dry-etched to transfer the pattern of the photoresist 1 to the hard mask 2 (FIG. 1C).

Then, the photoresist 1 after dry etching is removed by ashing. Here, the term “ashing” refers to a process for ashing and removing a photoresist by energy such as oxygen plasma.

In this process, residual materials such as incompletely ashed material 3 formed due to alteration of the photoresist 1 (hereinafter, referred to as “residual resist”) sometimes remain without being fully removed (FIG. 1D). Such a residual resist 3 remaining on a cleaned surface after ashing becomes an unwanted mask as a foreign matter, which inhibits processing of a processed object 7. For example, when a processed object 7 is an interconnection, a residue after etching due to processing inhibition may cause short circuit between adjacent interconnections. A residual resist must be, therefore, removed by washing.

Various process liquids have been studied for removing a residual resist remaining after ashing. For example, there has been proposed a process for removing a residual resist using DHF (diluted hydrofluoric acid). Alternatively, Japanese Laid-open Patent Publication No. 2006-106616 has disclosed the use of a process liquid comprising (a) at least one of a hydrogen peroxide solution (H₂O₂) and ozone water (O₃), (b) at least one of alkylene carbonates and its derivatives, and (c) water as a process liquid for removing a resist.

However, the removal technology of a residual resist using the abovementioned DHF or an etchant described in Japanese Laid-open Patent Publication No. 2006-106616 is assumed to be used for manufacturing a semiconductor device with lower integration degree.

Meanwhile, as semiconductor devices have been highly size-reduced, achieving a fine pattern in lithography has been a basic challenge in manufacturing a device. Thus, a laser of KrF, ArF or the like has been used as a light source having a shorter wavelength. For example, for producing a frontier semiconductor device with a highly reduced size, an ArF laser with a wavelength of 196 nm is used and a resist for forming a pattern is a resist exclusive to an ArF laser.

However, when processing by using a process liquid such as DHF for a long time for completely removing a residual resist 3, it may etch off another film exposed on a surface such as a hard mask 2, lead to deformation of a pattern form such as a hard mask 2 (FIG. 2A). On the other hand, when a time of processing with a process liquid such as DHF is reduced for preventing deformation of a hard mask 2 due to the process liquid, a residual resist 3 may be incompletely removed (FIG. 2B).

A process liquid described in Japanese Laid-open Patent Publication No. 2006-106616 contains at least one of a hydrogen peroxide solution (H₂O₂) and ozone water (O₃), and is thus harmful to humans and difficult to be handled and managed. Furthermore, since a hydrogen peroxide solution (H₂O₂) and ozone water (O₃) are so oxidative that they may deteriorate other parts in a device during removing a residual resist. For example, when a processed object is an interconnection made of a metal such as tungsten, a hydrogen peroxide solution or ozone water cannot be used because they can dissolute tungsten.

Furthermore, the technique for removing a residual resist using the abovementioned DHF or an etchant described in Japanese Laid-open Patent Publication No. 2006-106616 is assumed to be used for manufacturing a semiconductor device which has not been highly size-reduced, so that a little deviation in dimensional accuracy due to the use of the above etchant does not affect element properties. However, in producing a recent highly size-reduced semiconductor device, a slight deviation in dimensional accuracy due to removal of a residual resist using the above etchant may cause deterioration in element properties.

The use of a resist exclusive to an ArF laser as described above for manufacturing a highly fine semiconductor device is advantageous for forming a fine pattern while having a disadvantage of being less resistant to dry etching. Thus, for improving resistance to dry etching, a small amount of silicon is added to the dedicated resist. However, while such a small amount of silicon in the dedicated resist can improve resistance to etching of the resist, it frequently causes the problem of a residual resist.

In addition to the above process liquid, there have been investigated the use of process liquids containing various components for removing a residual resist. However, any of these process liquids is insufficient in the light of handling easiness and residual-resist removing performance. Furthermore, an environmentally harmful process liquid must be reprocessed after use, leading to increase in a manufacturing cost.

In view of the above situation, the present invention has been achieved, focusing on pure water to which attention has not been paid as a removal liquid of the residual resist because of its inability to remove a residual resist alone. Specifically, the objection of the present invention is to effectively and exclusively remove a residual resist without deterioration of the other parts in a semiconductor device by a two-step process of immersing a residual resist after ashing in pure water and then removing the residual resist by DHF.

### SUMMARY OF THE INVENTION

An embodiment of the present invention relates to a process for manufacturing a semiconductor device, comprising:

preparing a substrate in which a silicon-containing resist pattern is formed on a processed-material layer,

dry-etching the processed-material layer using the silicon-containing resist pattern as a mask to form a processed-material layer pattern,

ashing the silicon-containing resist pattern to leave a silicon-containing residual resist on the surface of the processed-material layer pattern,

immersing the substrate on which the silicon-containing residual resist remains into pure water to swell and deform the silicon-containing residual resist, and

immersing the substrate on which the swelled and deformed silicon-containing residual resist remains into diluted hydrofluoric acid to remove the silicon-containing residual resist from the substrate.

As a first effect of the present invention, a residual resist can be selectively removed without deterioration in the other parts in a semiconductor device, by immersion into pure water and removal by DHF after ashing.

As a second effect of the present invention, pure water is used as pretreatment for removal of a residual resist, so that removal by DHF can be performed under mild conditions. Thus, the residual resist can be removed without deterioration of a structure of the other parts in a semiconductor device such as a hard mask 2.

As a third effect of the present invention, pure water is used as a process liquid, so that removal by DHF can be performed under mild conditions. Thus, removal of a residual resist can be conducted for a long period without adversely affecting the structure of a semiconductor device. In addition, a residual resist is swollen and, therefore, easily removed.

As a fourth effect of the present invention, pure water is used as pretreatment for removing a residual resist, so that removal by DHF can be performed under mild conditions. Thus, DHF can be easily handled and managed.

As a fifth effect of the present invention, inexpensive and manageable pure water is used as pretreatment for removing a residual resist, so that a conventionally used highly oxidative, expensive and toxic process liquid can be reduced. Thus, a production cost can be reduced, environmental burdens can be decreased and a throughput can be improved.

### BRIEF DESCRIPTION OF THE DRAWINGS

FIG. 1 shows a process for manufacturing a related semiconductor device.

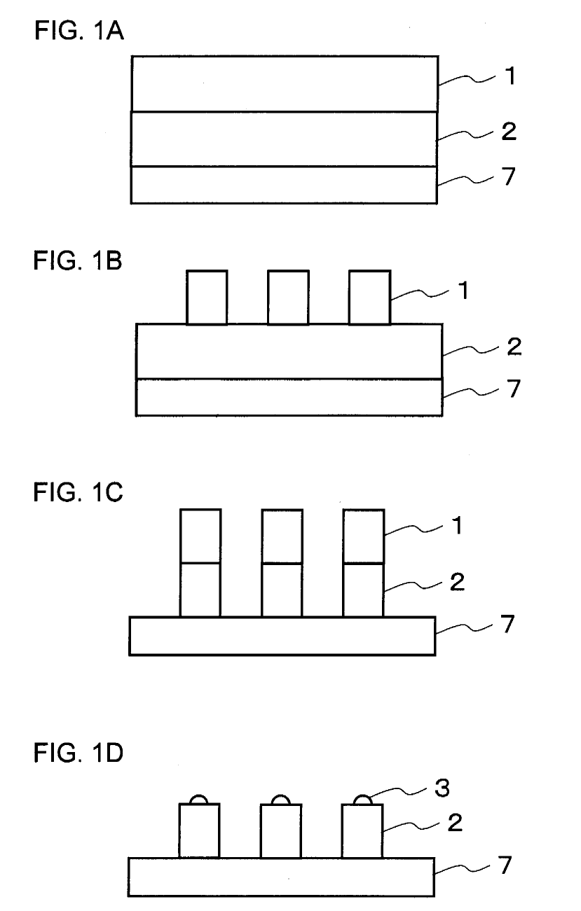

FIG. 2 shows a process for manufacturing a related semiconductor device.

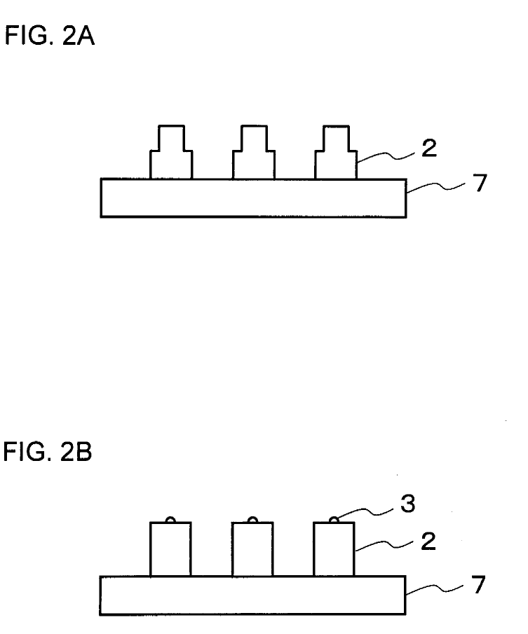

FIG. 3 shows an example of a process for manufacturing a semiconductor device according to the present invention.

In these drawings, the symbols have the following meanings; 1: resist mask, 2: hard mask, 3: residual resist, 4: Component F, 5: pure water, 6: swollen residual resist, and 7: processed object.

### DETAILED DESCRIPTION OF PREFERRED EMBODIMENTS

A process for manufacturing a semiconductor device of the present invention will be described, as an example, for processing of a gate electrode when forming a gate electrode interconnection of an MOS (metal oxide semiconductor) type transistor used in a DRAM (dynamic random access memory).

The gate electrode processing comprises:

preparing a substrate by forming a gate insulating film and a gate electrode material on a semiconductor layer, on which a hard mask layer is formed as a processed-material layer,

forming an antireflection film (BARC: bottom anti-reflective coating) and a silicon-containing photoresist on the hard mask layer,

forming a pattern of the silicon-containing photoresist and the antireflection film,

dry-etching the hard mask layer using the pattern of the silicon-containing photoresist and the antireflection film as a mask to form a hard mask pattern,

removing the silicon-containing photoresist pattern by ashing,

immersing a substrate with a silicon-containing residual resist on the hard mask pattern into pure water after the step of removing the silicon-containing photoresist pattern by ashing, to swell and deform the silicon-containing residual resist,

removing the swollen and deformed silicon-containing residual resist after immersing a substrate with a silicon-containing residual resist on the hard mask pattern into pure water, by DHF (Diluted Hydrofluoric Acid), and

dry-etching the gate electrode material using the hard mask pattern without a residual resist.

In the present invention, a desired shape of pattern is formed in a hard mask layer by dry etching, and then first, most of a resistor pattern is removed by ashing. In this step, part of the resistor pattern remains as a residual resist on the hard mask pattern. Subsequently, the substrate with the residual resist on the hard mask pattern surface is immersed into pure water (water-treatment step). In the step, a density of the residual resist is reduced due to swelling deformation (cubical expansion of the residual resist condensed during ashing). It is considered that resultantly, DHF can more easily permeate the residual resist during a later removing step by DHF treatment and adhesiveness of the residual resist to the substrate (the surface of the hard mask pattern) decreases, resulting in easier release of the residual resist from the substrate.

The hard mask layer is dry-etched using an at least fluorine-containing plasma. Thus, fluorine atoms have been incorporated in a residual resist to remain in the residual resist. It is considered that the fluorine atoms incorporated in the residual resist are eluted into water during the water-treatment step and form hydrofluoric acid, which can etch the residual resist itself. It has been, however, experimentally found that such etching by the eluted fluorine material is not so effective to cause dimensional variation in the hard mask.

This water-treatment step makes the residual resist very removable, so that the subsequent removal of the residual resist by DHF can be easily conducted under mild conditions. In the step, it is considered that the residual resist is removed by lift-off. In the present invention, removal of the residual resist by DHF can be easily conducted under mild conditions, so that dimensional variation in a hard mask pattern is not caused. Furthermore, an extremely fine gate electrode interconnection can be precisely formed in a resist pattern.

Furthermore, in the present invention, pure water is used for pre-treatment of removing a residual resist and the residual resist is removed by DHF under mild conditions. The residual resist can be, therefore, removed without deterioration in the other structural parts in a semiconductor device such as a hard mask and a metal interconnection layer under the hard mask. It allows for a long-term treatment, so that the residual resist can be easily removed after sufficient swelling. Furthermore, it results in reduction of the amount of a conventionally used highly oxidative, expensive and toxic process liquid, which allows for reduction of a manufacturing cost, reduction of environmental burdens and improvement in a throughput.

There will be the individual steps for processing the above gate electrode material in detail.

### The Step of Forming of a Gate Electrode Material and a Hard Mask on a Semiconductor Layer

In advanced products such as DRAMs, a polymetal structure is employed as a gate electrode. A polymetal structure is an electrode structure in which a metal such as a tungsten film is deposited on a polysilicon film. A gate electrode in a polymetal structure can be a low-resistance gate electrode because it contains a metal. As an example, there will be described formation of a gate electrode having this polymetal structure.

First, a gate insulating film is formed on the surface of a semiconductor layer, by thermal oxidation, then the above polymetal laminated film is formed over the whole surface of the gate insulating film. Here, a polysilicon film and a tungsten film are formed by CVD (Chemical Vapor Deposition) and sputtering, respectively.

Next, a hard mask layer is formed on the tungsten film. The hard mask layer is a two-layer film in which a silicon oxide film is deposited to a thickness of 70 nm on a silicon nitride film with a thickness of 140 nm. This silicon nitride film may be a monolayer. Also, a silicon oxide film may be a monolayer. These silicon nitride and silicon oxide films can be formed using plasma CVD.

In this example, the term “substrate” refers to a substrate having one or more layers such as a semiconductor layer, a gate insulating film, a gate electrode material and a hard mask layer. When a substrate consists of a plurality of layers, the etching step in the present invention may be dry etching to a single layer or to a plurality of layers.

### The Step of Forming an Antireflection Film and a Photoresist

After forming a hard mask layer, an antireflection film and a photoresist are formed on the hard mask layer in this order. These antireflection film and photoresist are formed by spin coating. They may be made of known materials, but photoresist is a resist film containing a small amount of silicon for being applicable to extremely fine processing. Specifically, the photoresist is a silicon-containing resist exclusively for ArF with a thickness of 98 nm. The amount of silicon contained in this resist is preferably 15 to 25 wt %, more preferably 20 wt %. The antireflection film is a polyhydroxystyrene resin with a thickness of 260 nm. The resist exclusively for ArF has a form of siloxane polymer.

When there is a material with a high optical reflectance under a photoresist, the above antireflection film is used for preventing the photoresist in an area to be untreated from being exposed by reflected light from the material. In particular, when a tungsten film is used as a gate electrode material as in this embodiment, an antireflection film is essential.

### The Step of Forming a Pattern of a Photoresist and an Antireflection Film

Then, a resist pattern having a desired pattern suitable to an intended semiconductor device is formed by photolithography using an ArF laser beam with a wavelength of 193 nm. Herein, the resist pattern has a width of 70 nm. Next, the resist pattern is transferred to the antireflection film by plasma etching. Since the antireflection film is an organic film mainly containing carbon, this plasma etching can be conducted by selecting gases such as oxygen, nitrogen, hydrogen and argon as appropriate.

If the resist exclusively for ArF does not contain silicon, during plasma etching of this antireflection film, the resist does not have sufficient etching resistance, so that the resist exclusively for ArF first disappears and thus a pattern of the antireflection film cannot be formed. When using a silicon-free resist exclusively for ArF with a large thickness of about 400 nm for preventing disappearance of the resist exclusively for ArF during etching, the problem of destruction of the resist itself cannot be avoided in a fine pattern with a pattern width of about 70 nm. It is, therefore, preferable that the resist exclusively for ArF contains silicon as in this example.

### The Step of Etching of a Hard Mask

After transferring the resist pattern to the antireflection film, the hard mask layer comprising a silicon oxide and a silicon nitride films is further dry-etched using the photoresist and the antireflection film as a mask, to transfer the pattern to the hard mask layer. This dry etching is conducted by a fluorine-containing plasma using, for example, tetrafluoromethane (CF₄) as an etching gas. Here, fluorine is introduced into the photoresist and the antireflection film as a mask.

### Ashing Step

After transferring the pattern to the hard mask layer, the resist pattern is removed by generating plasma of a reaction gas such as oxygen plasma.
The conditions of the plasma ashing may be, for example, as follows;
apparatus: λ-300 (Hitachi Kokusai Electric Inc.),
O₂gas: 13 SLM,
pressure: 4.5 Torr,
applied voltage: 4.5 kW,
time: 60 sec.

In the process, a silicon-containing residual resist remains in the surface of the hard mask pattern. In this example, a silicon-containing residual resist was found in the center of the upper surface of the hard mask (width: 70 nm) as a line pattern with a width of about 20 nm and a height of about 20 nm by observation of the state after ashing by SEM (Scanning Electron Microscopy).

### Water Treatment Step

In the step of water-treatment in the present invention, the substrate having a silicon-containing residual resist on the hard mask pattern is immersed into pure water (water-treatment step). Thus, in a subsequent removing step by DHF, the residual resist can be exclusively and effectively removed without deterioration in the other parts of the semiconductor device. It is considered to be because immersion of the substrate having the residual resist into pure water causes swelling and deformation of the residual resist, resulting in reduction of its density and reduction in adhesiveness of the residual resist to the substrate and therefore the residual resist can be easily detached from the substrate.

In this step, the surfaces of the silicon oxide and the silicon nitride films to be a hard mask pattern and the tungsten film to be a gate electrode are exposed, but these materials are not etched by pure water. This water-treatment step can be conducted under the conditions; for example, temperature: 25° C. and time: 80 sec. The water-treatment step may be conducted in warm water at 100° C. or lower, and a final removal efficiency of the residual resist can be improved. It is preferable that the water-treatment and the subsequent DHF-treatment steps are conducted using a sheet-feed washing machine where substrates are processed one by one, for improving controllability of a processing time.

### The Step of DHF Treatment

After the water-treatment step, the residual resist on the hard mask is removed using DHF (Diluted Hydrofluoric Acid) in a ratio of HF:H₂O=1:300 by volume. Here, a treatment time is for example 20 sec. The residual resist is highly removable owing to swelling and deformation in the previous water-treatment step. Thus, the residual resist can be easily removed by diluted hydrofluoric acid under mild conditions. In etching by the above DHF for 20 sec, the silicon oxide film is etched to 0.2 nm, which is substantially negligible in relation to the pattern width of 70 nm.

### The Step of Dry Etching of a Gate Electrode Material

Then, after removing the silicon-containing residual resist on the hard mask pattern by DHF, the gate electrode material comprising the tungsten and polysilicon laminated film is dry-etched using the hard mask pattern as a mask, to form a gate electrode interconnection. The dry etching may be plasma etching using a chlorine-containing gas.

### EXAMPLES

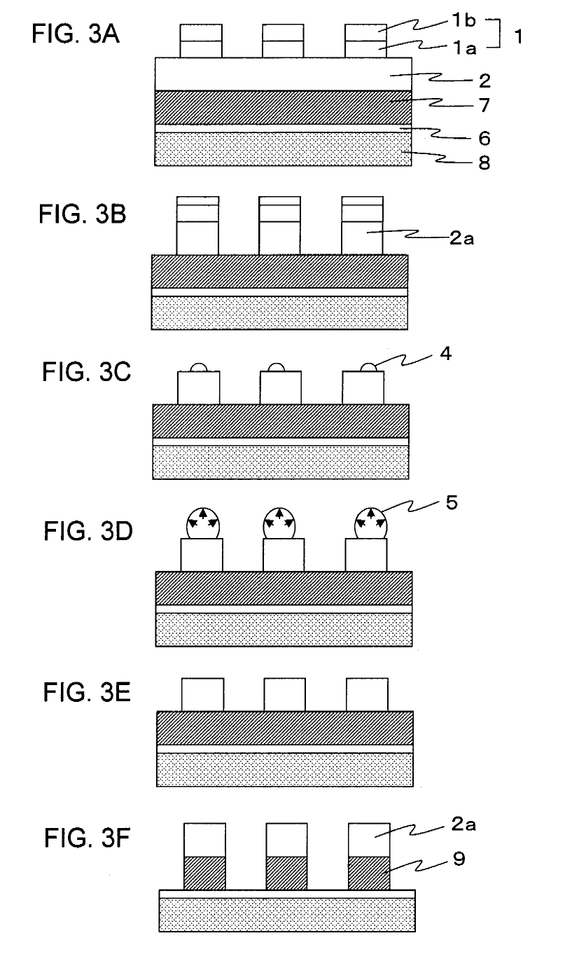

FIG. 3 shows an exemplary process for manufacturing a semiconductor device according to the present invention. There will be described processing of a substrate when using CF₄ as an etching gas in the step of etching a hard mask layer 2 formed on a gate electrode material 7.

First, as shown in FIG. 3A, a gate insulating film 6 was formed on the surface of the substrate 8, and then a gate electrode material 7 was formed as a laminated film comprising a polysilicon and a tungsten films. Furthermore, a hard mask layer 2 comprising a silicon nitride and a silicon oxide films was formed. Subsequently, a mask layer comprising an antireflection film la and a silicon-containing photoresist 1b was formed. Next, a mask pattern 1 comprising the antireflection film 1a and the silicon-containing photoresist 1b was formed by lithography.

Then, as shown in FIG. 3B, the hard mask layer 2 was dry-etched using the mask pattern 1 as a mask to form a hard mask pattern 2a. Next, as shown in FIG. 3C, the mask pattern 1 was removed by ashing. Here, a silicon-containing residual photoresist 4 remained on the hard mask pattern 2a.

Subsequently, as shown in FIG. 3D, the silicon-containing residual photoresist 4 on the hard mask pattern 2 after ashing was subjected to water-treatment in pure water (room temperature: 25° C., time: 80 sec). This water treatment was conducted using a sheet-feed washing machine. Consequently, the silicon-containing residual photoresist 4 was transformed into a swollen residue 5 by water absorption.

Then, as shown in FIG. 3E, the swollen residual resist 5 was treated with DHF in a ratio of HF:H₂O=1:300 for 20 sec using a sheet-feed washing machine, to remove the residual resist 5. In a separately conducted pilot experiment, the residual resist 5 had been removed after 15 sec treatment.

Then, as shown in FIG. 3F, the gate electrode material 7 was dry-etched using the hard mask pattern 2a as a mask to form a gate electrode 9. Then, a semiconductor device can be obtained after ion implantation, formation of an interlayer insulating film, formation of an upper interconnection layer and the like.

In this embodiment, water treatment of the residual resist 4 is followed by DHF treatment. By this water treatment, the residual resist 4 becomes the swollen residual resist 5, whose adhesiveness to an interface with the hard mask pattern 2a is reduced, so that the residual resist 5 becomes more removable from the hard mask pattern 2a. As a result, the residual resist 6 can be effectively removed under very mild conditions in the subsequent DHF treatment. Although the silicon oxide, the silicon nitride and the tungsten films are exposed during the water treatment, this step is conducted not with a reactive liquid such as an ozone-containing solution, an amine-containing solution and an HF-containing solution but with pure water alone. Therefore, the residual resist can be removed without damaging the silicon oxide, the silicon nitride and the tungsten films. Thus, a highly precise gate electrode pattern can be formed.

The manufacturing process according to the present invention is not limited to formation of a gate electrode, but can be applied to a process for forming a metal interconnection pattern in which a lower interconnection layer is exposed. For example, in the case of a DRAM (Dynamic Random Access Memory), the process can be applied to a word interconnection or a bit interconnection. An interconnection layer may be, in addition to a tungsten interconnection, an aluminum interconnection, a copper interconnection and a GST (Ge—Sb—Te alloy) interconnection which is a phase change material.

### Comparative Example

In the above process for manufacturing of the present embodiment, treatment by DHF was conducted under the same conditions directly after ashing without water treatment, and the state was observed by SEM. It was found that a residual resist remained with a width of 20 nm and a height of 20 nm on the upper surface of the hard mask as islands. In other words, it indicates that the residual resist cannot be removed by 20 sec treatment with DHF in a dilution ratio of HF:H₂O=1:300.

On the other hand, the residual resist can be completely removed using a higher concentration of DHF (for example, HF:H₂O=1:20 by volume), allowing for eliminating the step of water treatment. However, SEM observation of the resultant semiconductor device indicated that in addition to the substrate, the hard mask was etched, leading to dimensional variation by about 5 to 10 nm. Thus, as described in the section “BACKGROUND OF THE INVENTION”, it is found that desired transistor properties cannot be achieved by comparative example.

Although there has been described the present invention with reference to Example, the present invention is not limited to the above Example. The constitution and specific details in the present invention can be variously modified within the technical scope of the present invention in a manner which can be understood by one of ordinary skill in the art.

What is claimed is:

1. A process for manufacturing a semiconductor device, comprising:
preparing a substrate in which a silicon-containing resist pattern is formed on a processed-material layer,
dry-etching the processed-material layer using the silicon-containing resist pattern as a mask to form a processed-material layer pattern,
ashing the silicon-containing resist pattern to leave a silicon-containing residual resist on the surface of the processed-material layer pattern,
immersing the substrate on which the silicon-containing residual resist remains into pure water to swell and deform the silicon-containing residual resist, and
immersing the substrate on which the swelled and deformed silicon-containing residual resist remains into diluted hydrofluoric acid to remove the silicon-containing residual resist from the substrate.

2. The process for manufacturing a semiconductor device as claimed in claim 1, wherein the processed-material layer is a hard mask layer formed on a metal interconnection layer.

3. The process for manufacturing a semiconductor device as claimed in claim 2, wherein the hard mask layer is a silicon oxide film, a silicon nitride film or a laminated film comprising a silicon oxide and a silicon nitride films.

4. The process for manufacturing a semiconductor device as claimed in claim 1, wherein an antireflection film is further formed between the processed-material layer and the silicon-containing resist pattern.

5. The process for manufacturing a semiconductor device as claimed in claim 1, wherein in the step of dry-etching the processed-material layer, dry etching is conducted using an at least fluorine-containing gas.

6. The process for manufacturing a semiconductor device as claimed in claim 2, wherein in the step of immersing the substrate into pure water, the upper surfaces of the processed-material layer pattern and the metal interconnection layer in the substrate are exposed.

7. The process for manufacturing a semiconductor device as claimed in claim 1, wherein the steps of immersing the substrate into pure water and into diluted hydrofluoric acid are conducted using a sheet-feed washing machine.
